(19) United States
(12) Patent Application Publication
(10) Pub. No.: US 2018/0331685 A1
(43) Pub. Date: Nov. 15, 2018

(54) Touch Pad Button System for Electric Door Operators

(71) Applicant: TX QSE, LLC, Corpus Christi, TX (US)

(72) Inventor: David D. Olson, Duluth, MN (US)

(21) Appl. No.: 15/976,744

(22) Filed: May 10, 2018

Related U.S. Application Data
(60) Provisional application No. 62/504,064, filed on May 10, 2017.

(51) Int. Cl. H03K 17/96; E05F 15/614

(52) U.S. Cl. CPC H03K 17/96; E05F 15/614; E05Y 2201/434; H03K 2217/96015; E05Y 2400/66; E05Y 2400/612; E05Y 2900/132; E05Y 2400/86

(57) ABSTRACT

A touch pad button system for electric door operators is comprised of a touch pad, an electric door operator in communication with the touch pad, and a door operable by the electric door operator pursuant to a predefined set of instructions. The door and the electric door operator are at a location remote from the touch pad. The touch pad includes a tactile sensing member, a shorting pad, a bottom circuit and a dielectric member. The touch pad also has a power source and transmitter for sending signals received by a tactile sensing member to the electric door operator. An adhesive adheres the touch pad to a surface. Upon receiving a signal, the electric door operator opens a door pursuant to a predefined set of instructions. The door and electric door operator are at a location remote from the touch pad.

### CROSS REFERENCE TO RELATED APPLICATIONS

This original non-provisional application claims priority to and the benefit of U.S. provisional application Ser. No. 62/504,064, filed May 10, 2017, and entitled “Touch Pad Button for Electric Door Operators,” which is incorporated by reference herein.

### STATEMENT REGARDING FEDERALLY SPONSORED RESEARCH OR DEVELOPMENT

None.

### BACKGROUND OF THE INVENTION

### 1. Field of the Invention

The present invention relates to a door operator. More specifically, the present invention relates to a touch pad button system for electric door operators for industrial and commercial use.

### 2. Description of the Related Art

Automated door openers or operators are used to assist in opening swing doors. These door operators attach to swing doors, such as one might find at hospitals, grocery stores or retail stores and assist in automating the process of opening the swing doors, generally through the use of a motor having received a signal from a motion sensor or a push button. The motor, connected to an arm attached to the swing door, then either opens or closes the swing door via the arm. The door operators may be oriented in any number of directions depending on the direction of the swing of the swing door, as described in U.S. Pat. No. 8,720,113, which is incorporated by reference herein.

There exist different types of push switches or push buttons used to open swing doors. These buttons are sometimes called “push buttons” because to open up the doors, the buttons need to be “pushed.” Many of them contain moving parts and have push plates that contain switches that wear out and fail.

Generally, at hospitals, when one goes up to a door that is automatically controlled, for individuals who require the door to open, they can press a button on the side of the doorway. Pressing or pushing the button with sufficient force triggers a signal that will make the door open. However, these buttons are extremely cumbersome, have a tall profile such that they extend too far from the wall, can be complicated in circuitry and, because of their moving parts, tend to break down requiring constant maintenance to ensure their operability.

Regarding hospital applications, those in the prior art contain spaces between the button and the wall to which they are attached. These spaces are narrow enough that they cannot be cleaned efficiently or completely. This leads to a very fertile breeding ground for germs and other bacteria to flourish in this area.

Many times, physicians and/or medical staffer cannot reach to press the push button because their hands are preoccupied tending to a patient being moved on a gurney.

Therefore, there is a need for a touch activated button system which contains no moving parts, has a low profile and contains antimicrobial properties that can be quickly and easily installed at a convenient location to operate door operators reliably.

### BRIEF DESCRIPTION OF THE SEVERAL VIEWS OF THE DRAWINGS

FIG. 1 is a front view of an embodiment of the present invention.

FIG. 2 is a side view of an embodiment of the present invention.

FIG. 3 shows a perspective back view of the present invention.

FIG. 4 depicts a partial side view of an embodiment of the present invention.

FIG. 5 shows a front view of an alternative embodiment of the present invention in a circular configuration.

FIG. 6 shows a back view with respect to FIG. 5 of an alternative embodiment of the present invention in a circular configuration.

FIGS. 7A and 7B depicts a partial exploded front view of an alternative embodiment of the present invention illustrating features therein.

FIGS. 8A and 8B show front views of the internal components of a shorting pad and bottom circuit of an alternative embodiment of the present invention illustrating features therein.

FIG. 9 depicts a front view of an internal component of a dielectric of an alternative embodiment of the present invention illustrating features therein.

FIG. 10 depicts a front view of an alternative embodiment of the present invention integrated with a power supply box.

FIG. 11 depicts a side view with respect to FIG. 10 of an alternative embodiment of the present invention.

FIG. 12 is a front view of an alternative embodiment of the present invention integrated with a power supply box.

FIG. 13 is a back perspective view with respect to FIG. 12 of an alternative embodiment of the present invention integrated with a power supply box.

FIG. 14 is a left side perspective view of an alternative embodiment of the present invention with respect to FIG. 12 with the cover of the power supply box removed.

FIG. 15 is a right side perspective view of an alternative embodiment of the present invention with respect to FIG. 12 with the cover of the power supply box removed.

FIGS. 16-24 depict various positions of a door being opened with the present invention being used, from the initial touch pad activation by a user, to activation of the door operator to open the door, to the opening and closing of the door.

### BRIEF SUMMARY OF THE INVENTION

The present invention is a touch pad button system for electric door operators. The touch pad is comprised of at least a “touch” material meaning that when a user touches the material, the tactile pressure triggers a sensor that opens or closes a circuit which in turns closes the door. Only slight tactile pressure is necessary. The touch material is essentially an on/off and “hold open” switch and contains LEDs on this switch. The present invention does not contain any moving parts and is covered by a material, such as plastic, having antimicrobial properties.

In contrast to bacteria promoting conditions of existing models, the present invention completely seals the wall due to the adhesive used therein and prohibits any growth of germs. This is because the adhesive is stuck so close to the wall that it leaves no gap between the button and the wall for bacteria on which to grow. The profile of the present invention once attached extends only slightly above the wall to which the present invention is attached.

The location of the present invention on the wall varies depending on circumstances. In one embodiment, the touch pad button is at a height above the floor high enough such that a physician or other user can hit the button with their elbow to open the doors. Concerning the distance between the button touch pad and the door it controls, in some instances, the distance should be sufficiently long enough to provide enough time to hit the button with, for example, a gurney; such that the doors are opened by the time the gurney gets to the door. In another embodiment, the button touch pad may be placed at such a level as to enable a person using a wheelchair to active the touch pad by kicking it with a foot.

The touch pad button has a good “feel.” In addition, because it is so closely adhered to the wall to which it attaches with no gap therein between, the present invention can easily be hosed off (along with the wall to which it is attached) with disinfectant with no negative effect thereto.

The present invention may be used as an on-off or activation switch for any application needing a low voltage switch. Battery life is extended in light of the low voltage requirements. Though several variants of push switches currently exist in the market, the present invention addresses the shortcomings of what is currently available. For example, current push plates have switches that wear out and fail. However, the present invention contains no moving parts. The present invention has been successfully tested to 7 million touches. Existing models lose their paint and finish after a short length of time. However, the present invention contains an anti-microbial surface which works much better than the copper and brass that are on the market today.

Existing models use screws or other types of fasteners that can damage the wall to which they are mounted. When they are subsequently removed, repairs are needed to repair damage to the wall. The present invention, however, causes no damage to the wall or other surface to which it mounts. The present invention uses a “peel and stick” installation method to install the present invention to a surface quickly, cleanly and efficiently.

Existing models are cumbersome and have a high profile when mounted such that they stick out from the wall at a distance of about 1.5 to 2 inches. The present invention has a low profile when mounted. It is believed to be the flattest unit (at least flatter than all other existing models) providing a profile significantly less than existing models.

The present invention makes it easier to open the door using these types of “push buttons.” Particular, the present invention requires one to only touch the button and then it will activate to open up the door. Not as much force and energy by a user is require to have the door open. In addition, the “button” itself is comprised of an entire touch pad made of material which is sun proof, UV proof and generally weather proof, making the present invention very durable. Generally, it is preferable to have the present invention work in pairs, such that they may function to activate a door operator on both sides of a doorway, e.g., one for inside the door and one for outside the door. The present invention may also be wireless.

### DETAILED DESCRIPTION OF THE INVENTION

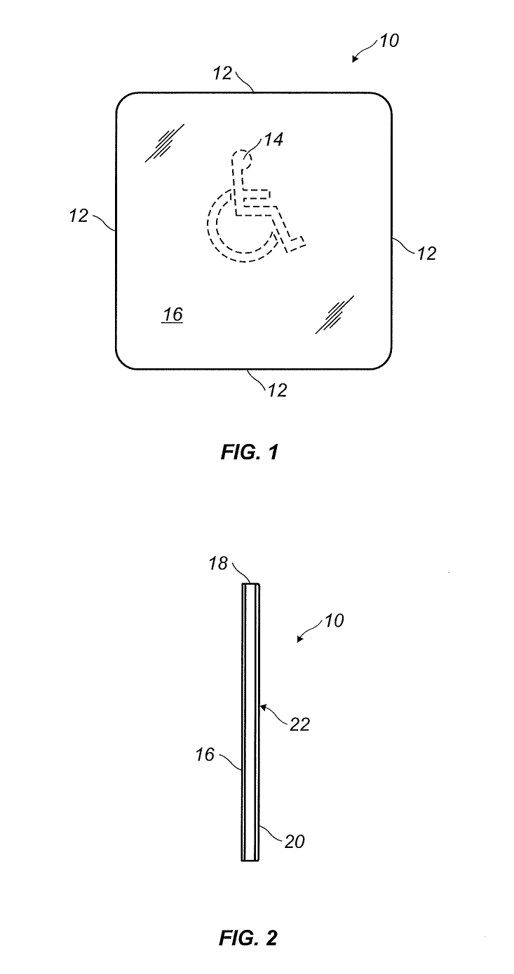

Referring now to FIG. 1, the touch pad 10 of the present invention is shown. In one embodiment, the touch pad 10 is configured into a quadrilateral configuration with sides 12 having the lengths of approximately 4 to 4.5 inches. A logo 14 or other insignia may be included on the front exterior surface 16 of the touch pad 10 to denote functionality. For example, a logo 14 of the International Wheelchair Symbol may be placed on the surface 16 of the touch pad 10 to denote access for people with disabilities, particularly those bound to a wheelchair, as shown in FIG. 1.

Referring now to FIG. 2, the touch pad 10 of the present invention is comprised of a plurality of members or layers. For example, the outer layer or exterior surface 16 of the touch pad 10 is comprised of antimicrobial material and may be silk screened with a logo 14 or other insignia, as indicated above (see, e.g., FIG. 1). A middle layer 18 is comprised of a machine plastic backing. An interior layer 20 is comprised of a peel-and-stick adhesive 22 able to withstand 200 mph winds.

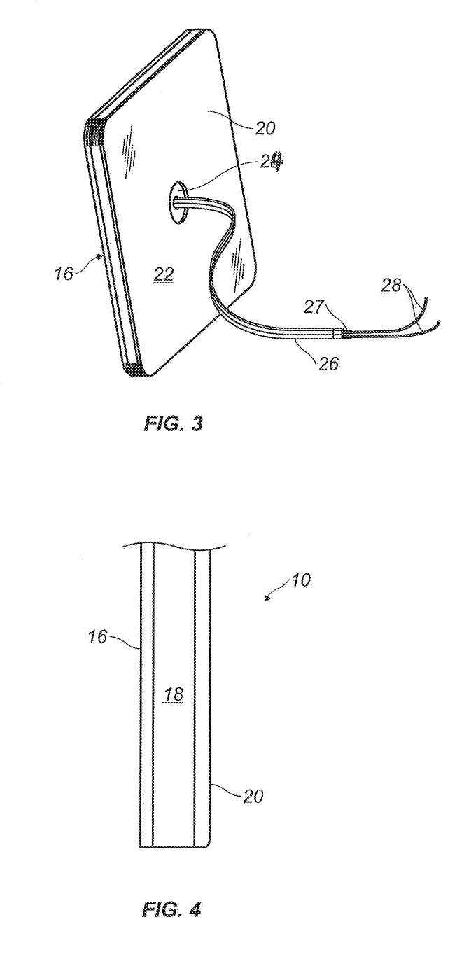

Referring now to FIGS. 3 and 4, an aperture 24 at the center of the back surface 20 of the touch pad 10 allows for internal wiring 26 to be pulled through. Wiring 26 is flat. Leads 28 attached to the wiring 26 via contacts 27, such as by soldering, allow the touch pad 10 to be electrically connected to other components (not shown). The touch pad 10 measures approximately ⅛ of an inch in width. However, other dimensions may be used and still remain within the contemplation of the present invention.

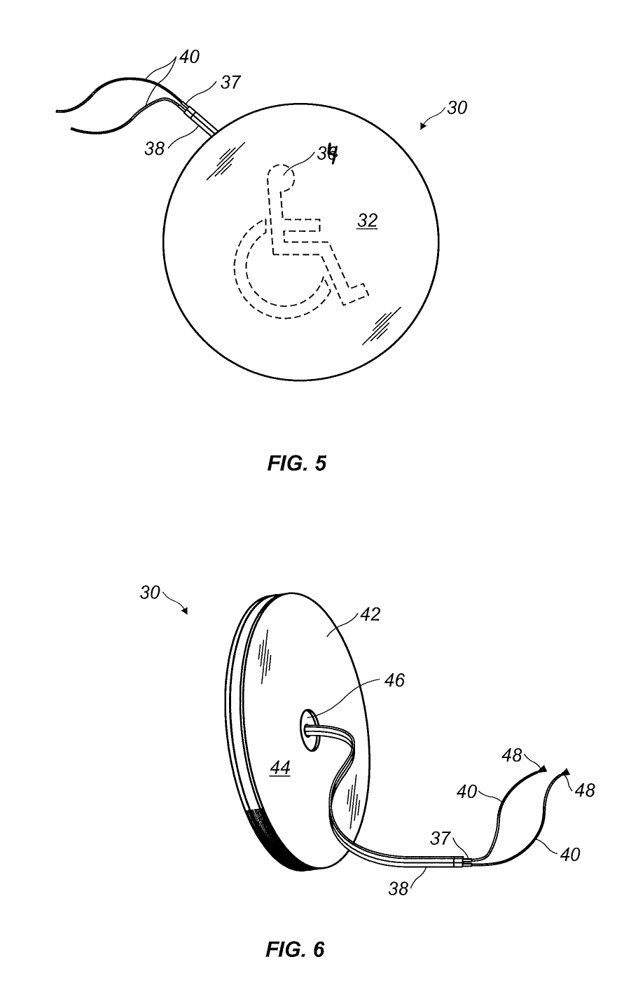

In another embodiment, the touch pad 30 of the present invention may be in a circular configuration, as shown in FIGS. 5 and 6. The back surface 42 of the circularly configured touch pad 30 of the present invention utilizes an adhesive 44, as shown in FIG. 6. The adhesive 44 used is 3M 468 MP, 200 MP adhesive. However, other comparable adhesives may be used and still remain within the contemplation of the present invention. The circular configuration of the touch pad 30 is approximately 6 inches in diameter with a width of ⅛ inch thick. An aperture 46 at the center of the back surface 42 of the touch pad 30 (similar to the aperture 24 in the quadrilaterally configured touch pad 10) allows for internal wiring 38 to be pulled through. As shown in FIG. 6, leads 40 attached to the wiring 38 via contacts 37, such as by soldering, allow the touch pad 30 to be electrically connected at ends 48 of leads 40 to other components.

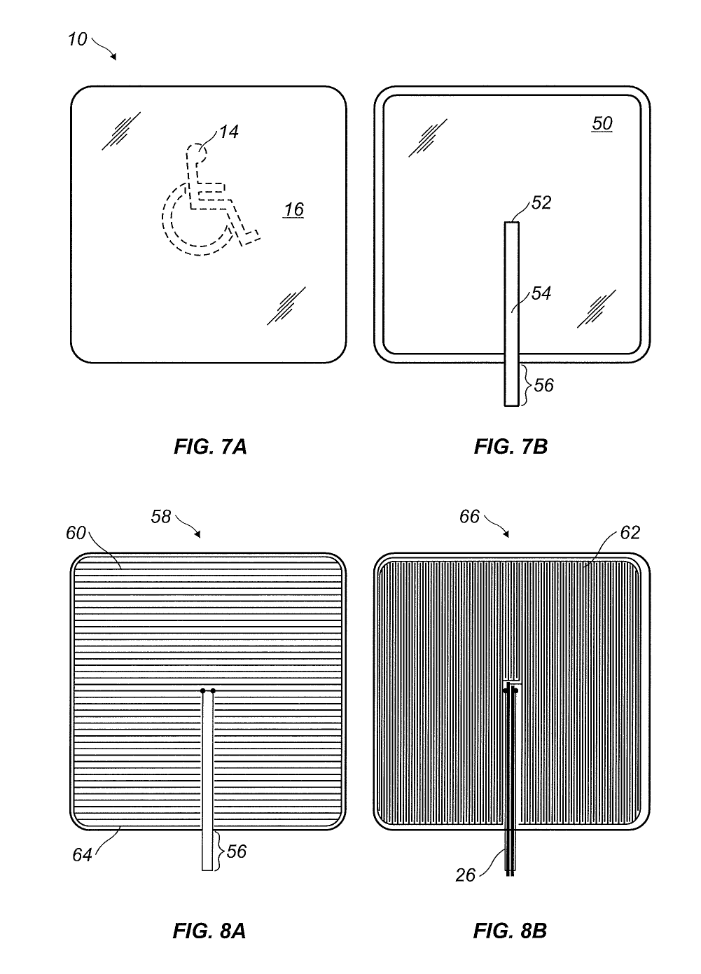

Referring now to FIGS. 7A and 7B, a partial exploded view of the quadrilaterally configured touch pad 10 of the present invention is shown. FIG. 7A shows the logo 14 or other indicia may appear on the surface 16 of the face panel as well as any other notice or text desired. In FIG. 7B, a spacer 50 includes a cut out portion 52 therein. The spacer 50 is a double-sided adhesive. One side of spacer 50 adheres to the back side of the face panel 16, accommodating and securing the face panel 16 therein. A strip 54 made of a thicker double-sided adhesive is attached to and fits substantially within cut out portion 52, except a tail portion 56 of the strip 54, which extends beyond the boundaries of the spacer 50 and face panel 16 once adhered to each other. When front panel 16 and spacer 50 are adhered together, strip 54 is adhered to the front panel 16 on one side.

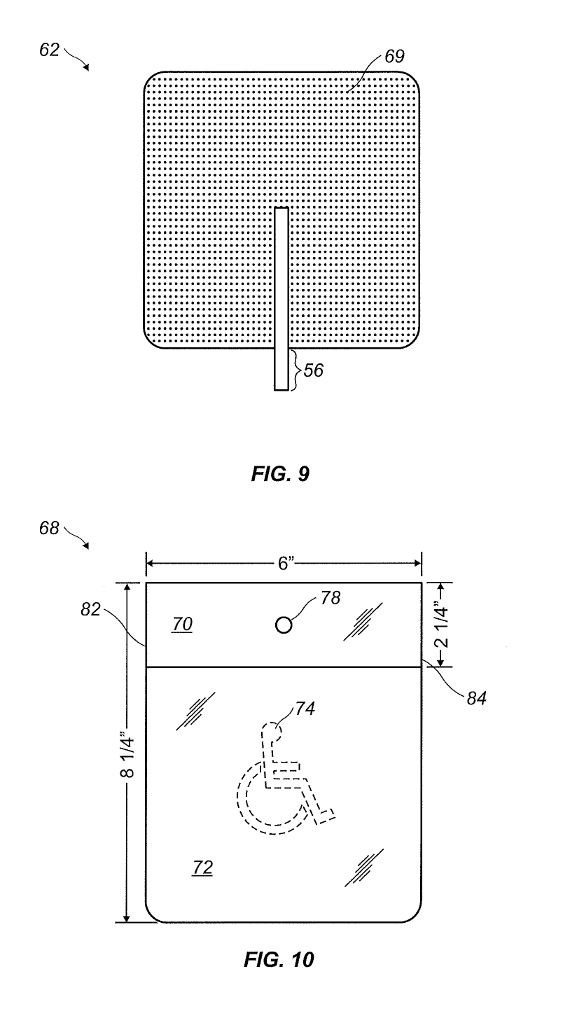

Referring now to FIGS. 8A, 8B and 9, a shorting pad 58, bottom circuit 66 and dielectric 67 are shown. Each of these components is as member or layer of the touch pad and is attached to each other to form a single unit (see e.g., FIG. 3). Each of these components is in electric communication with each other. The back of the front panel 16 adheres to the front side of spacer 50. The back side of spacer 50 adheres to shorting pad 58. In other words, the spacer 50 is positioned between and is adhered to both front panel 16 and shorting pad 58. The shorting pad 58 contains wiring 60 therein. The shorting pad 58 is attached to the bottom circuit 66 via an adhesive strip 64 that traverses along the perimeter of the shorting pad 58. Adhesive strip 64 is double-sided thereby adhering to the shorting pad 58 on one side and the bottom circuit 66 on the other side. A dielectric 67 is integrated within bottom circuit 66. On the side of the bottom circuit 66 opposite of where the shorting pad 58 is attached, the bottom circuit 66 with dielectric 67 is attached via an adhesive to the middle layer 18 (not shown). The selective adhesive or backing adhesive (not show) covers the back non-conductive side of the touch pad except for the tail 56. These internal components illustrate the internal wiring and sensors required to detect tactile pressure.

Still referring to FIGS. 7-9, the face panel 16 is made of an Autotex F8 anti-microbial textured polyester material. The dimensions of the face panel 16 are 6.50″×6.50″ with four 0.50″ radius corners. The face panel 16 prints subsurface with the background printing and is generally of a dark blue color background, with white VF Series Flat Vinyl Screen Ink (VF-112) text or logo 14 thereon though other colors having comparable adhesive, rigidity and flexibility qualities may be used and still remain within the contemplation of the present invention. It is, however, preferable that there be contrast between the background and the graphics or text such that the graphics or text stands out. The spacer 50 is a 3M Double Coated Membrane Switch Spacer 7956MP double-sided adhesive. The bottom circuit 66 is a folding circuit. The folding circuit is 0.005 Mylar A 9120. The folding circuit prints conductive silver followed by UV dielectric, as discussed above and as shown in FIG. 8B and 9. The selective/backing adhesive (see FIG. 3) is also made of 3M #7956 double-sided adhesive. The contacts 27 are tin female crimplex #14106-12(2) with a nicomatic wire assembly. The power supply (not shown) of the present invention is capable of providing sustained high-power.

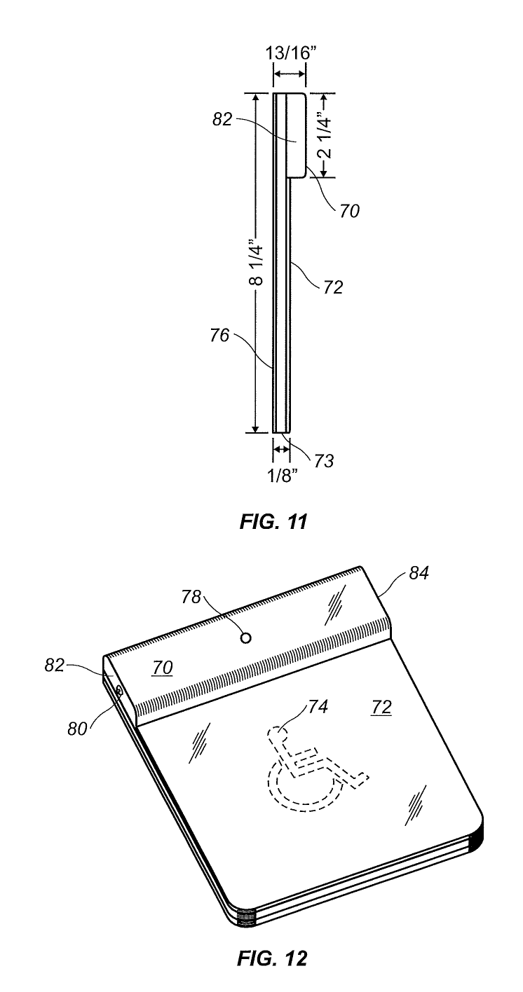

Referring now to FIG. 10, in another embodiment, the touch pad 68 of the present invention may be wireless and incorporate a power supply box or housing 70. For example, as shown in FIG. 10, the power supply box 70 of the wireless touch pad 68 has the dimensions of 6 inches long by 2¼ inch wide. Together with the touch pad 68, the dimensions for this embodiment of the present invention are 8¼ inches long by 6 inches wide. Referring to FIG. 11, a side view of the wireless touch pad 68 is shown. The dimensions are 8¼ inches long along the back 76 by ⅛ inch wide at the bottom end 73 below the power supply box 70. The power supply box dimensions are 13/16 inches in height by 2¼ inch in width. Though the present invention uses these dimensions, other dimensions may be used and still remain within the contemplation of the present invention.

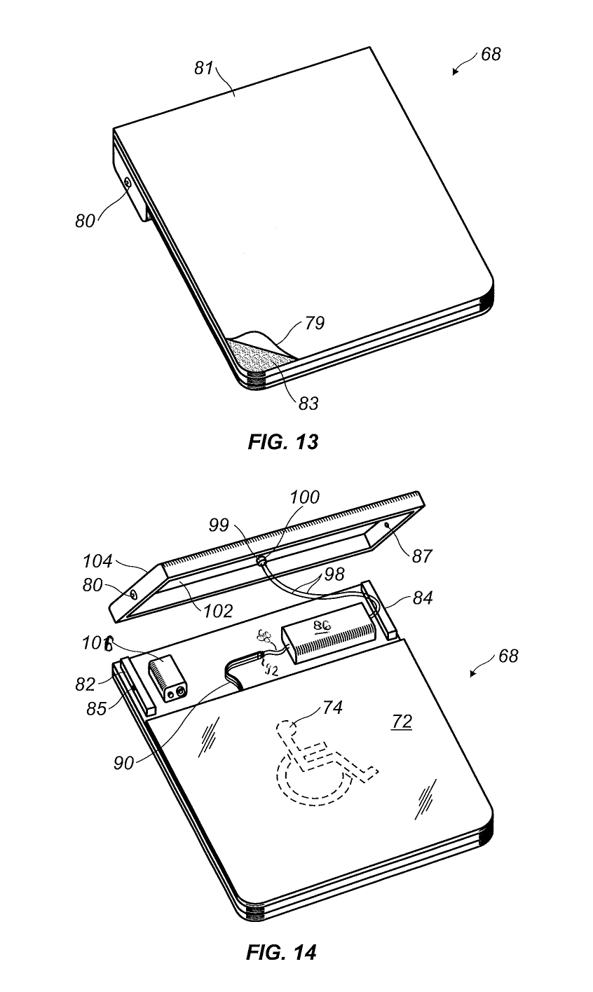

Referring now to FIGS. 12 through 15, the wireless touch pad 68 has a power supply box 70 connected with and adjacent to the touch pad 68. The power supply box 70 contains an LED light 78 in the center of the outer portion of the power supply box 70, as shown in FIG. 12. A plurality of fasteners 80 (only one of which is visible in FIGS. 12 and 13) is used to secure the power supply box 70 to the touch pad 68. The fasteners 80 attach the power supply box 70 at each end 82, 84 to walls inside the power supply box 70, as shown in FIGS. 13 through 15. The touch pad 68 has a front panel 72 upon which a logo 14 or other indicia as well as text, if desired, may be placed. Adhesive 79 on the back surface 81 of touch pad 68 can be pulled off exposing the adhesive surface 83 which will adhere to a surface, e.g., wall. The present invention uses screws as fasteners to secure the power supply box 70 to the touch pad 68. However, other comparable fasteners may be used and still remain within the contemplation of the present invention.

Referring now to FIG. 14, the present invention may also include an electronic improved retriever and transmitter 86. Cover 104 is secured to the power supply box 70 with a plurality of fasteners 80 which traverse through apertures 87 (i.e., screw holes) within ends 82 and 84. Removing cover 104 of the power supply box 70 from the touch pad exposes the components therein. The components include a power source, a retriever and transmitter and an LED light contact, all in electrical communication with each other via wiring. The wiring 90 coming from the touch pad 68 (in FIG. 14, the wiring is coming out the top of the front panel 72) are connected via contacts 92 to leads 88 which connects to the retriever and transmitter 86. Wiring 98 then connects the retriever and transmitter 86 to the LED light contact 99 to activate and illuminate upon receiving a signal, as shown in FIG. 14. An aperture 100 is at the center of the inside surface 102 of cover 104. The LED light contact 99 fits within the aperture 100. The LED light 78 at the end of the LED light contact 99 is visible from outside the power supply box 70 (see FIG. 12).

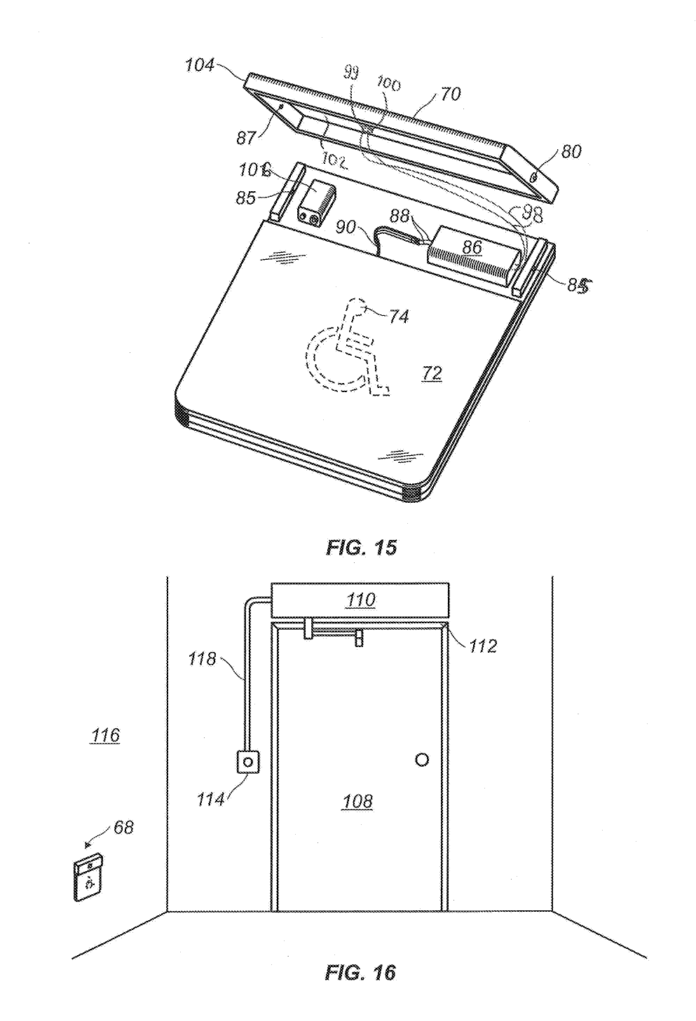

Referring now to FIG. 15, the power supply box 70 is located at the top (or bottom) of the touch pad 68 and is easily accessible. A battery 106 is also included in the power supply box 70. The battery 106 has a three to five year battery life and further contains a low battery light indicator. The present invention uses batteries, such as alkaline and lithium batteries, which may be rechargeable, though other kinds of comparable battery may be used and still be within the contemplation of the present invention. The LED light 78 functions both to illuminate when the touch pad has registered the requisite tactile force necessary to close a circuit therein, causing a signal to be transmitted to a controller of a door operator at a remote location to open the door, and to blink repeatedly and continuously, noting the battery life of battery 106 will soon be expiring. The present invention currently uses a 9V battery 106, though other battery sizes sufficient to provide the required voltage may be used and still remain within the contemplation of the present invention.

Concerning the mounting of the touch pad to a surface, the present invention is a “peel and stick” type of installation, facilitated through the use of an adhesive and covering of same. The covering is peeled and the present invention can be adhered to or stuck on a surface, such as a wall, at the desired location.

The round or circularly configured touch pad 30 (FIGS. 5 and 6) are hardwired and may have a diameter of 6 inches and 4 inches. There are no moving parts. The surface contains an antimicrobial coating. The installation of the touch pad to a surface can be easily done through a “peel and stick” install. Once installed, the 200 MP adhesive prevents the touch pad (in any embodiment) from separating from the surface to which the touch pad adheres. The wireless touch pad (FIGS. 10-15) also contains no moving parts and includes an antimicrobial coating on the surface. Installation is similarly done using a “peel and stick” method using 200 MP adhesive. The present invention has a low profile once mounted. As the surface has no wear surfaces, the present invention also has a long wear life. Silk screen graphics may be displayed on the outer surface which makes for quick and economical design changes.

The dimensions for the wireless touch pad include having a ⅛ inch thick bottom and a 1 inch thick top. An LED light 78 comes on during activation (once sufficient tactile pressure is detected) to show the system is working. The LED light 78 blinks to indicate the battery is low in charge, i.e., “low battery.”

In use, touching the surface of the touch pad sends a signal to and activates the receiver/transmitter 86, e.g., completes a circuit, that sends a signal to a controller located at a location remote from the touch pad. The controller then sends a signal to the door operator which then activates the swing door gear box or door operator and motor thereof to open the swing door to be compliant with the Americans with Disabilities Act (ADA).

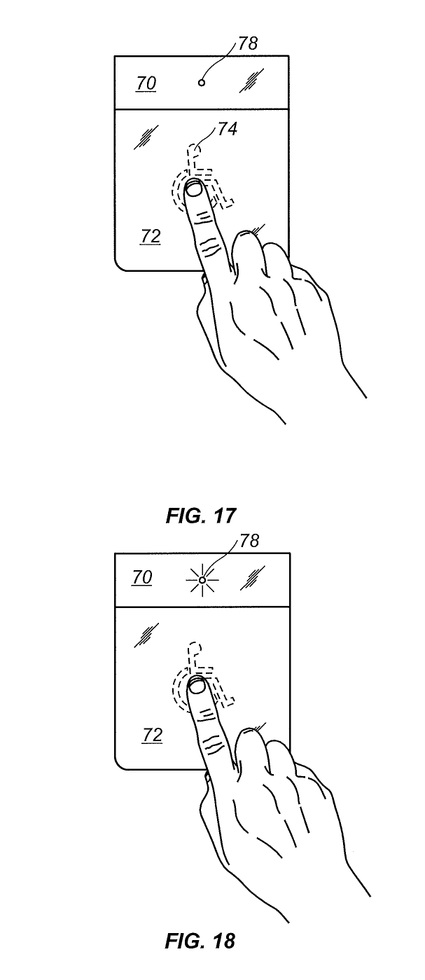

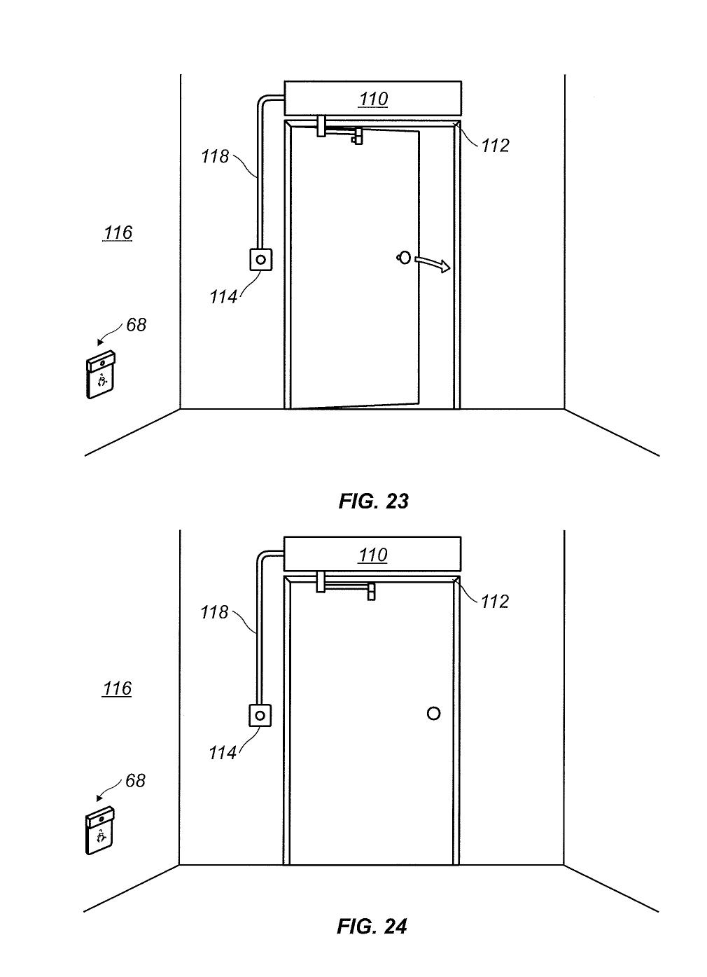

Referring now to FIGS. 16 through 24, the present invention in use will be described. Referring to FIG. 16, a door 108 at a remote location from the touch pad 68 is connected to a door operator 110 mounted above the door jamb 112 is shown. A controller 114 is electrically connected to the door operator 110. The door operator 110 is in electronic communication with the touch pad 68 mounted on the wall 116 via the controller 114, as shown in FIG. 17. Referring now to FIG. 18, to activate and open up the door 108, a user provides a slight tactile pressure (e.g., touch) upon the touch pad 68. The user may touch the touch pad 68 at any particular area of the front panel. Once the user touches the touch pad 68, this causes the touch pad 68 to send a signal to the door operator 110. The signal from the touch pad may be sent over to the controller via hardwire or via wireless communication. Confirmation that the signal is sent is given by the light indicator 118 which may be of any desired color. The present invention, for example, uses a green colored light indicator.

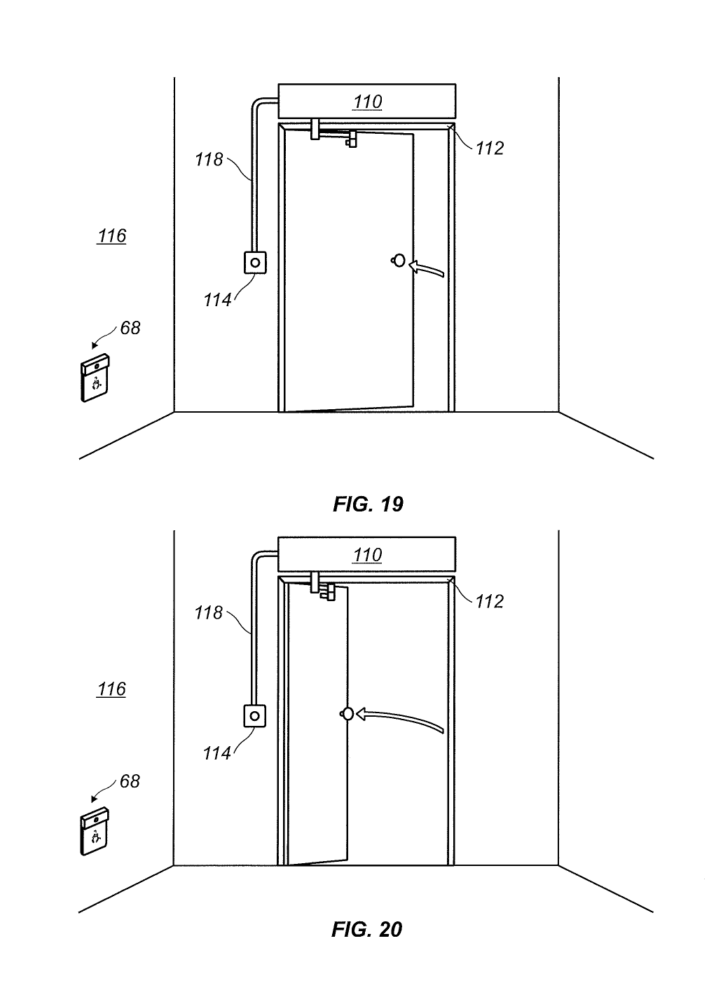

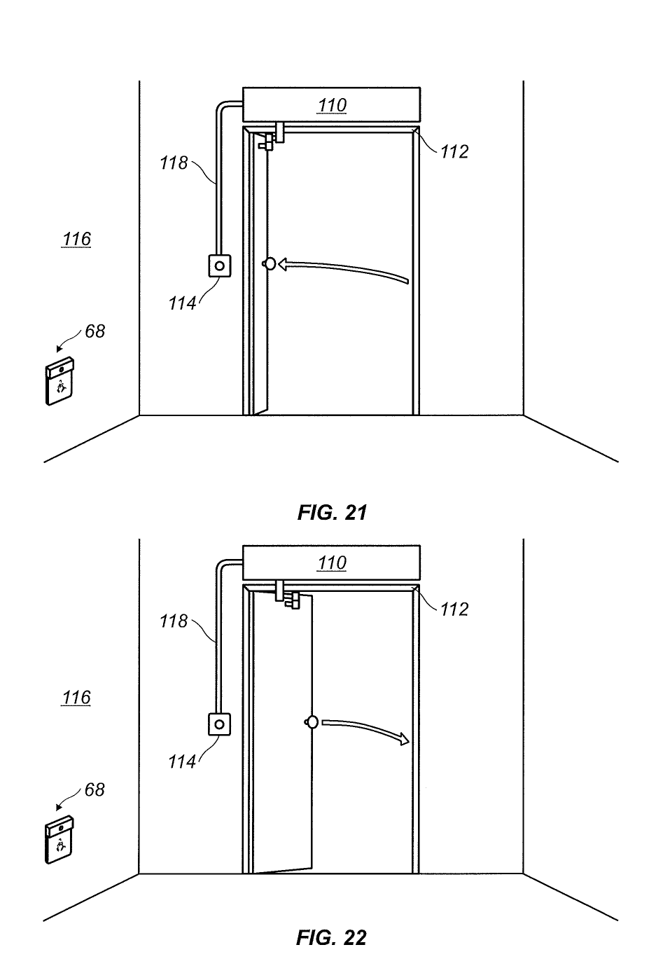

Once the signal is transmitted over to the door operator 110 via the controller 114, the signal causes the door operator 110 to open the door, as shown in FIG. 19. The door 108 will continue to swing open until completely opened, as shown in FIGS. 19 through 21. After the door has been completely opened (FIG. 21), the door will stay in the completely opened position for a desired preprogrammed amount of time pursuant to a predefined set of instructions before beginning to close, as shown in FIGS. 22 through 24.

While the present invention is described as being electrically connected to the controller for the door operator, the present invention may also be wireless and send and receive signals via Bluetooth® or other comparable wireless technology platform.

The present invention has application in the medical industry by hospital staff, including physicians, nurses, emergency medical technicians (EMTs), and paramedics, where patients are rolled on gurneys from one area of a hospital (e.g., admittance or emergency room) to another (e.g., surgery, recovery) and the use of the physicians' hands are preoccupied by tending to the patient. However, it is contemplated that the present invention may also have application in other areas such as hotels, restaurants, commercial buildings and warehouses, where large doors require automatic opening to, for example, allow physically impaired individuals easy access into such structures (where it may be difficult otherwise) or to allow large items to be pushed through on rollers where individuals are handling the deliverables and cannot easily open such doors.

The various embodiments described herein may be used singularly or in conjunction with other similar devices. The present disclosure includes preferred or illustrative embodiments of specifically described apparatuses, assemblies, and systems. All various steps concerning the method or methods disclosed in the present invention are not necessarily described in a particular order such that, for example, one step is required prior to the procession of another step. Alternative embodiments of such apparatuses, assemblies, and systems can be used in carrying out the invention as described and as claimed herein and such alternative embodiments are limited only by the claims themselves. Other aspects and advantages of the present invention may be obtained from a study of this disclosure and the drawings, along with the appended claims.

I claim:

1. A touch pad button system for electric door operators comprising:
a touch pad comprised of:
a tactile sensing member;
a shorting pad electrically connected to said tactile sensing member;
a bottom circuit electrically connected to said shorting pad and said tactile sensing member;
a dielectric member integrated with said bottom circuit;
an adhesive connected to said bottom circuit for adhering to a surface;
a power supply housing having a cover, said power supply housing attached to said tactile sensing member;
a power source within said power supply housing;
a transmitter in electronic communication with said power source, said transmitter within said power supply housing;
an electric door operator in communication with said touch pad; and
a door operable by said electric door operator pursuant to a predefined set of instructions, wherein said door and said electric door operator are at a location remote from said touch pad.

2. The touch pad button system, as recited in claim 1, further comprising a second adhesive positioned between said tactile sensing member and said shorting pad.

3. The touch pad button system, as recited in claim 2, further comprising a spacer positioned between said tactile sensing member and said bottom circuit.

4. The touch pad button system, as recited in claim 3, further comprising indicia on the surface of said tactile sensing member.

5. The touch pad button system, as recited in claim 4, wherein said tactile sensing member further comprises an antibacterial material.

6. The touch pad button system, as recited in claim 5, wherein said touch pad has a low profile.

7. The touch pad button system, as recited in claim 6, further comprising a controller in electrical communication with said electric door operator.

8. The touch pad button system, as recited in claim 7, wherein said touch pad communicates with said controller wirelessly.

9. The method for installation of a touch pad system for electronic door operators, said method comprising the steps of:
locating a surface at a location remote from an electronic door operator;
determining the location on said surface of installation of a touch pad;
removing the adhesive layer from a side of a touch pad; and
adhering said touch pad to said surface at said desired location.

10. The method of use of a touch pad system for electronic door operators, said method comprising the steps of:
applying tactile pressure to a tactile pressure sensing member;
sensing said tactile pressure satisfying a predefined pressure threshold;
transmitting a signal to a receiver;
relaying said signal to a controller for an electronic door operator, said controller at a location remote from said tactile pressure sensing member;
sending said to an electronic door operator; and
opening a door connected to said electronic door operator.

11. The method of claim 10 wherein said opening step further comprises rotating an arm connected at one end to said electronic door operator and at the other end to said door, said door opening and remaining open at a predefined rate pursuant to predefined set of instructions.

12. The method of claim 11 further comprising the step of closing said door.
